(19) United States
(12) Patent Application Publication
(10) Pub. No.: US 2025/0098489 A1
(43) Pub. Date: Mar. 20, 2025

(54) DISPLAY DEVICE AND MOBILE ELECTRONIC DEVICE INCLUDING THE SAME

(71) Applicant: Samsung Display Co., LTD., Yongin-si (KR)

(72) Inventor: Chun Gi YOU, Yongin-si (KR)

(21) Appl. No.: 18/795,635

(22) Filed: Aug. 6, 2024

(30) Foreign Application Priority Data
Sep. 20, 2023 (KR) 10-2023-0125878

(51) Int. Cl. H10K 59/80; G02B 27/01

(52) U.S. Cl. CPC H10K 59/873; G02B 27/0172; G02B 2027/0178

(57) ABSTRACT

According to one or more embodiments, a display device may include a display panel including a display panel having a display area in which a light-emitting element is located, and a non-display area outside the display area in plan view and including a permeation prevention region outside an encapsulation area, and a crack prevention region outside the permeation prevention region and in a double line shape at at least one corner of the display panel.

### CROSS-REFERENCE TO RELATED APPLICATION

The present application claims priority to, and the benefit of, Korean Patent Application No. 10-2023-0125878, filed on Sep. 20, 2023, in the Korean Intellectual Property Office, the entire disclosure of which is incorporated herein by reference.

### BACKGROUND

### 1. Field

The present disclosure relates to a display device and a mobile electronic device including the same.

### 2. Description of the Related Art

Wearable devices in which a focus is formed at a distance close to user's eyes have been developed in the form of glasses or a helmet. For example, the wearable device may be a head mounted display (HMD) device or AR glasses. The wearable device provides an augmented reality (AR) screen or a virtual reality (VR) screen to a user.

The wearable devices, such as the HMD device or the AR glasses, may suitably use a display specification of at least 2000 PPI (pixels per inch) so that a user may use it for a long time without dizziness. To this end, organic light-emitting diode on silicon (OLEDoS) technology that is a high-resolution small organic light-emitting display device is emerging. The OLEDoS is a technology in which an organic light-emitting diode (OLED) is located on a semiconductor wafer substrate on which a complementary metal oxide semiconductor (CMOS) is located.

In general, a method of manufacturing a display device includes manufacturing a plurality of display panels (a plurality of cells) on one mother substrate, a sawing process of cutting the manufactured display panels from the mother substrate, and a grinding process of polishing the corners of each display panel into a round shape after the sawing process. The conventional manufacturing method of a display device may cause a problem that a display panel is damaged during the sawing process and/or the grinding process, or moisture and oxygen permeate into the display panel due to the damage.

### SUMMARY

Aspects of the present disclosure provide a display device capable of protecting a display panel from cracks that may occur during a sawing process and a grinding process, and capable of reducing or preventing moisture and oxygen permeating into the display panel, and a mobile electronic device including the same.

According to one or more embodiments of the present disclosure, a display device may include a display panel including a display panel having a display area in which a light-emitting element is located, and a non-display area outside the display area in plan view and including a permeation prevention region outside an encapsulation area, and a crack prevention region outside the permeation prevention region and in a double line shape at at least one corner of the display panel.

The display device may further include a driving circuit at one end of the display panel, wherein the display panel is defined includes a first corner and a second corner adjacent to the driving circuit, and a third corner and a fourth corner not adjacent to the driving circuit, and wherein the crack prevention region is in the double line shape at the third corner and the fourth corner of the display panel.

The crack prevention region may be in a single line shape at the first corner and the second corner of the display panel.

The crack prevention region may be in a right triangular shape at the third corner or the fourth corner of the display panel.

At the third corner or the fourth corner of the display panel, the crack prevention region may include a first portion forming a part of a first side surface of the display panel, a second portion extending from the first portion in a vertical direction to form a part of a second side surface of the display panel, and a third portion to connect the first portion to the second portion in a diagonal direction.

At the third corner or the fourth corner of the display panel, the permeation prevention region may be inside the third portion of the crack prevention region to be in parallel with the third portion.

At the third corner or the fourth corner of the display panel, a dummy structure may be in the crack prevention region in the right triangular shape.

The display panel may include a semiconductor substrate, a semiconductor backplane above the semiconductor substrate, a light-emitting element backplane having metal layers, and a light-emitting element layer above the light-emitting element backplane.

A stacked structure of the permeation prevention region may include permeation prevention metal layers at a same layer as the metal layers of the light-emitting element backplane.

A stacked structure of the crack prevention region may include permeation prevention metal layers at a same layer as the metal layers of the light-emitting element backplane.

According to one or more embodiments of the present disclosure, a mobile electronic device may include a display panel including a display area in which a light-emitting element is located, and a non-display area outside the display area and including a permeation prevention region outside an encapsulation area, and a crack prevention region outside the permeation prevention region in a double line shape at at least one corner of the display panel.

The mobile electronic device may further include a driving circuit at one end of the display panel, wherein the display panel includes a first corner and a second corner adjacent to the driving circuit, and a third corner and a fourth corner not adjacent to the driving circuit, and wherein the crack prevention region is in the double line shape at the third corner and the fourth corner of the display panel.

The crack prevention region may be in a single line shape at the first corner and the second corner of the display panel.

The crack prevention region may be in a right triangular shape at the third corner or the fourth corner of the display panel.

At the third corner or the fourth corner of the display panel, the crack prevention region may include a first portion forming a part of a first side surface of the display panel, a second portion extending from the first portion in a vertical direction to form a part of a second side surface of the display panel, and a third portion to connect the first portion to the second portion in a diagonal direction.

At the third corner or the fourth corner of the display panel, the permeation prevention region may be inside the third portion of the crack prevention region to be in parallel with the third portion.

At the third corner or the fourth corner of the display panel, a dummy structure may be inside the crack prevention region in the right triangular shape.

The display panel may include a semiconductor substrate, a semiconductor backplane above the semiconductor substrate, a light-emitting element backplane having metal layers, and a light-emitting element layer above the light-emitting element backplane.

A stacked structure of the permeation prevention region may include permeation prevention metal layers at a same layer as the metal layers of the light-emitting element backplane.

A stacked structure of the crack prevention region may include permeation prevention metal layers at a same layer as the metal layers of the light-emitting element backplane.

In accordance with the display device and the mobile electronic device including the same, according to embodiments, it is possible to protect a display panel from cracks that may occur during a sawing process and a grinding process, and to reduce or prevent moisture and oxygen permeating into the display panel.

### BRIEF DESCRIPTION OF DRAWINGS

The above and other aspects of the present disclosure will become more apparent by describing in detail embodiments thereof with reference to the attached drawings, in which:

FIG. 1 is a perspective view illustrating a head mounted display device according to one or more embodiments;

FIG. 2 is an exploded perspective view illustrating an example of the head mounted display device of FIG. 1;

FIG. 3 is a perspective view illustrating a head mounted display device according to one or more embodiments;

FIG. 4 is an exploded perspective view showing a display device according to one or more embodiments;

FIG. 5 is a layout view illustrating an example of the display panel shown in FIG. 4;

FIG. 6 is a block diagram illustrating a display device according to one or more embodiments;

FIG. 7 is an equivalent circuit diagram of a first sub-pixel according to one or more embodiments;

FIG. 8 is a layout view illustrating pixels of a display area according to one or more embodiments;

FIG. 9 is a cross-sectional view illustrating an example of the display device taken along the line A-A′ of FIG. 8;

FIG. 10 is a diagram illustrating an example of a mother substrate for manufacturing a display panel according to one or more embodiments;

FIG. 11 is an enlarged plan view of a third corner of the display panel according to one or more embodiments;

FIG. 12 is an enlarged plan view of a fourth corner of the display panel according to one or more embodiments; and

FIG. 13 is a partial cross-sectional view of the display panel, illustrating a stacked structure of a crack prevention region and a permeation prevention region according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

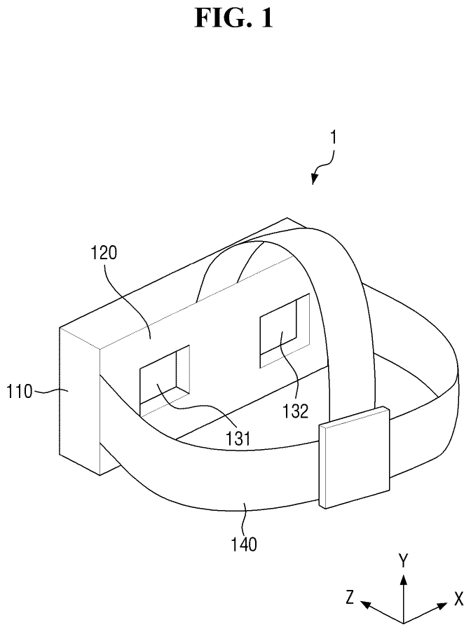

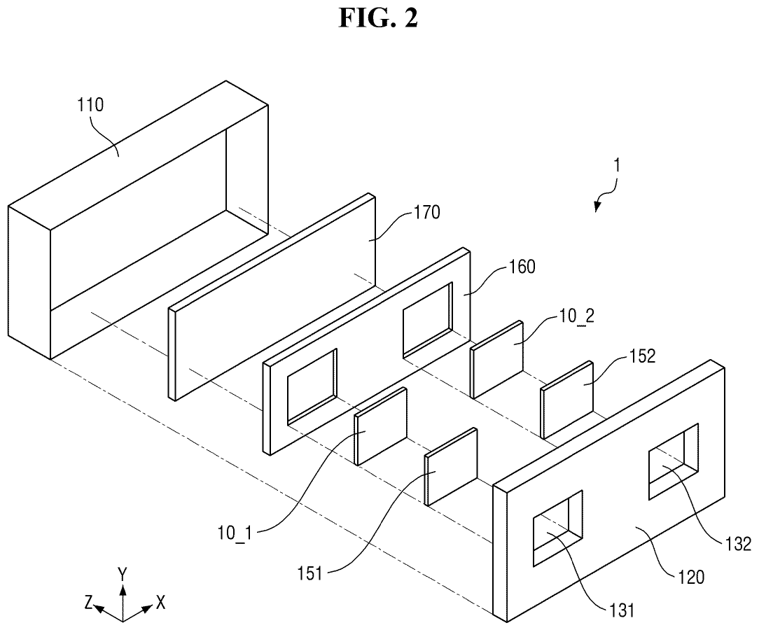

FIG. 1 is a perspective view illustrating a head mounted display device according to one or more embodiments. FIG. 2 is an exploded perspective view illustrating an example of the head mounted display device of FIG. 1.

Referring to FIGS. 1 and 2, a head mounted display device 1 according to one or more embodiments includes a first display device 10_1, a second display device 10_2, a display device housing 110, a housing cover 120, a first eyepiece 131, a second eyepiece 132, a head mounted band 140, a middle frame 160, a first optical member 151, a second optical member 152, a control circuit board 170, and a connector.

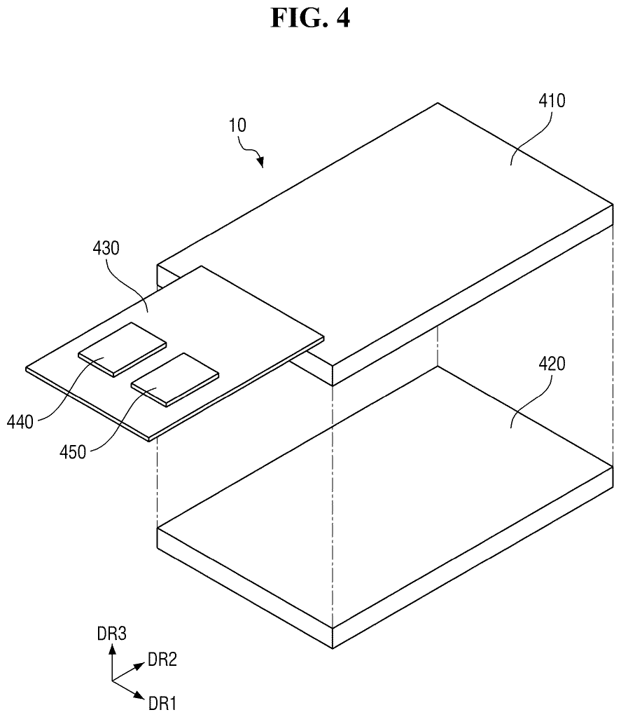

The first display device 10_1 provides an image to the user's left eye, and the second display device 10_2 provides an image to the user's right eye. Each of the first display device 10_1 and the second display device 10_2 is substantially the same as the display device 10 described with reference to FIGS. 4 to 13.

Therefore, the description of the first display device 10_1 and the second display device 10_2 will be replaced with the description with reference to FIGS. 4 to 13.

The first optical member 151 may be located between the first display device 10_1 and the first eyepiece 131. The second optical member 152 may be located between the second display device 10_2 and the second eyepiece 132. Each of the first optical member 151 and the second optical member 152 may include at least one convex lens.

The middle frame 160 may be located between the first display device 10_1 and the control circuit board 170, and may be located between the second display device 10_2 and the control circuit board 170. The middle frame 160 serves to support and fix the first display device 10_1, the second display device 102, and the control circuit board 170.

The control circuit board 170 may be located between the middle frame 160 and the display device housing 110. The control circuit board 170 may be connected to the first display device 10_1 and the second display device 10_2 through the connector. The control circuit board 170 may convert an image source inputted from the outside into digital video data DATA, and transmit the digital video data DATA to the first display device 10_1 and the second display device 10_2 through the connector.

The control circuit board 170 may transmit the digital video data DATA corresponding to a left eye image suitable for a user's left eye to the first display device 10_1, and may transmit the digital video data DATA corresponding to a right eye image suitable for a user's right eye to the second display device 10_2. Alternatively, the control circuit board 170 may transmit the same digital video data DATA to the first display device 10_1 and the second display device 10_2.

The display device housing 110 serves to store the first display device 10_1, the second display device 10_2, the middle frame 160, the first optical member 151, the second optical member 152, the control circuit board 170, and the connector. The housing cover 120 is located to cover one opened surface of the display device housing 110. The housing cover 120 may include the first eyepiece 131 on which the user's left eye is located and the second eyepiece 132 on which the user's right eye is located. Although it is illustrated in FIGS. 1 and 2 that the first eyepiece 131 and the second eyepiece 132 are located separately, the present disclosure is not limited thereto. The first eyepiece 131 and the second eyepiece 132 may be integrated into one piece.

The first eyepiece 131 may be aligned with the first display device 10_1 and the first optical member 151, and the second eyepiece 132 may be aligned with the second display device 10_2 and the second optical member 152. Therefore, a user may view the image of the first display device 10_1 magnified as a virtual image by the first optical member 151 through the first eyepiece 131, and may view the image of the second display device 10_2 magnified as a virtual image by the second optical member 152 through the second eyepiece 132.

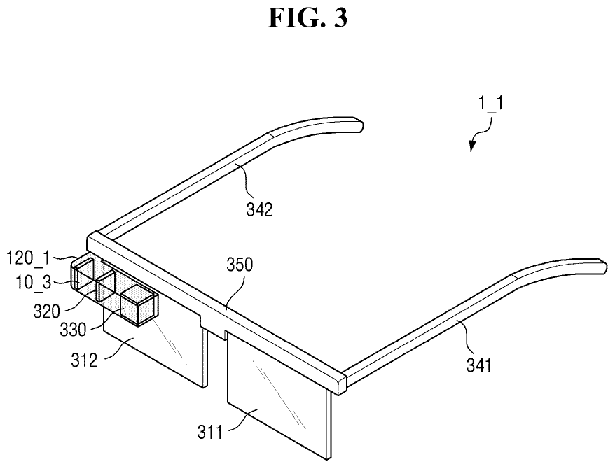

The head mounted band 140 serves to fix the display device housing 110 to a user's head, so that the state in which the first eyepiece 131 and the second eyepiece 132 of the housing cover 120 are respectively located at a user's left eye and a user's right eye may be maintained. When the display device housing 110 is implemented as a light and small device, the head mounted display device 1 may include an eyeglass frame, as shown in FIG. 3, instead of the head mounted band 140.

In addition, the head mounted display device 1 may further include a battery for supplying a power, an external memory slot capable of storing an external memory, an external connection port for receiving an image source, and a wireless communication module. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 3 is a perspective view illustrating a head mounted display device according to one or more embodiments.

Referring to FIG. 3, a head mounted display device 1_1 according to one or more embodiments may be a glasses-type display device in which a display device housing 120_1 is implemented as a relatively light and relatively small device. The head mounted display device 1_1 according to one or more embodiments may include a display device 10_3, a left lens 311, a right lens 312, a support frame 350, temples 341 and 342, an optical member 320, an optical path changing member 330, and the display device housing 120_1.

The display device 10_3 shown in FIG. 3 is substantially the same as the display device 10 described with reference to FIGS. 4 to 13. Therefore, the description of the first display device 10_1 and the second display device 10_2 will be replaced with the description with reference to FIGS. 4 to 13.

The display device housing 120_1 may include the display device 10_3, the optical member 320, and the optical path changing member 330. The image displayed on the display device 10_3 may be magnified by the optical member 320, may have an optical path changed by the optical path changing member 330, and may be provided to a user's right eye through the right lens 312. Accordingly, the user may view an augmented reality image in which a virtual image displayed on the display device 10_3 through the right eye and a real image seen through the right lens 312 are combined.

Although it is illustrated in FIG. 3 that the display device housing 120_1 is located at the right end of the support frame 350, the present disclosure is not limited thereto. For example, the display device housing 120_1 may be located at the left end of the support frame 350, and in this case, the image of the display device 103 may be provided to the user's left eye. Alternatively, the display device housing 120_1 may be located at both the left end and the right end of the support frame 350, and the user may view the image displayed on the display device 10_3 through both the left eye and the right eye.

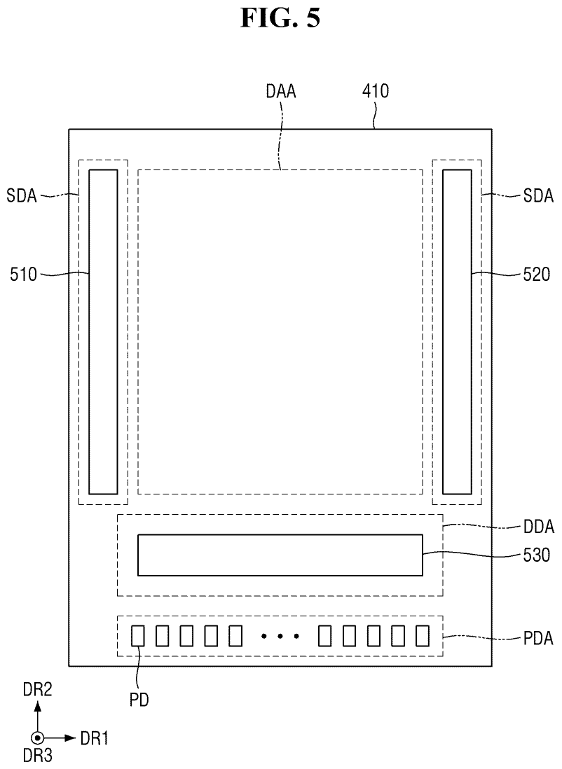

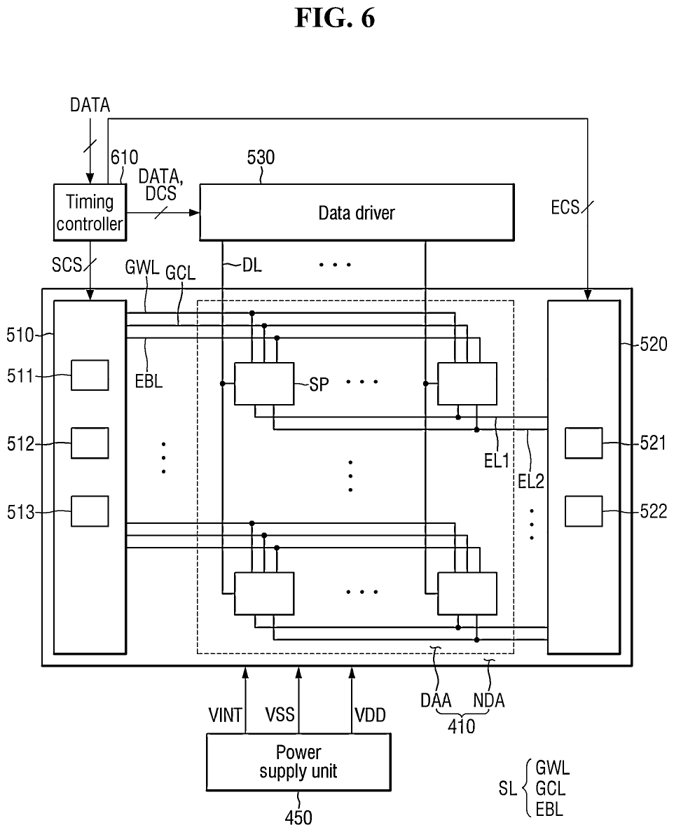

FIG. 4 is an exploded perspective view showing a display device according to one or more embodiments. FIG. 5 is a layout view illustrating an example of the display panel shown in FIG. 4. FIG. 6 is a block diagram illustrating a display device according to one or more embodiments.

Referring to FIGS. 4 and 5, a display device 10 according to one or more embodiments is a device displaying a moving image or a still image. The display device 10 according to one or more embodiments may be applied to portable electronic devices, such as a mobile phone, a smartphone, a tablet personal computer, a mobile communication terminal, an electronic organizer, an electronic book, a portable multimedia player (PMP), a navigation system, an ultra-mobile PC (UMPC) or the like. For example, the display device 10 may be applied as a display of a television, a laptop, a monitor, a billboard, or an Internet-of-Things (IoT) device.

Alternatively, the display device 10 may be applied to a smart watch, a watch phone, a head mounted display (HMD) for implementing virtual reality and augmented reality, and the like.

The display device 10 according to one or more embodiments includes a display panel 410, a heat dissipation layer 420, a circuit board 430, and a timing control circuit 440.

The display panel 410 may have a planar shape similar to a quadrilateral shape. For example, the display panel 410 may have a planar shape similar to a quadrilateral shape having short sides in a first direction DR1, and long sides in a second direction DR2 crossing the first direction DR1. In the display panel 410, a corner where a short side in the first direction DR1 and a long side in the second direction DR2 meet may be right-angled or rounded with a curvature (e.g., predetermined curvature). The planar shape of the display panel 410 is not limited to a rectangular shape, and may be a shape similar to another polygonal shape, a circular shape, or an elliptical shape. The planar shape of the display device 10 may follow the planar shape of the display panel 410, but the present disclosure is not limited thereto.

The display panel 410 includes a display area DAA for displaying an image, and a non-display area NDA for not displaying an image as shown in FIG. 5.

As shown in FIG. 6, the display area DAA includes a plurality of pixels PX, a plurality of scan lines SL, a plurality of emission control lines EL, and a plurality of data lines DL.

The plurality of pixels PX include a light-emitting element LE for emitting light. The plurality of pixels may be arranged in a matrix form in the first direction DR1 and the second direction DR2. The plurality of scan lines SL and the plurality of emission control lines EL may extend in the first direction DR1, while being 1 arranged in the second direction DR2. The plurality of data lines DL may extend in the second direction DR2, while being arranged in the first direction DR1.

The plurality of scan lines SL include a plurality of write scan lines GWL, a plurality of control scan lines GCL, and a plurality of bias scan lines EBL. The plurality of emission control lines EL include a plurality of first emission control lines EL1 and a plurality of second emission control lines EL2.

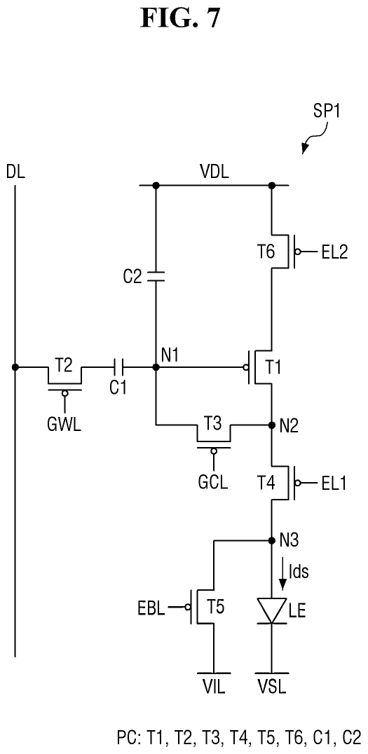

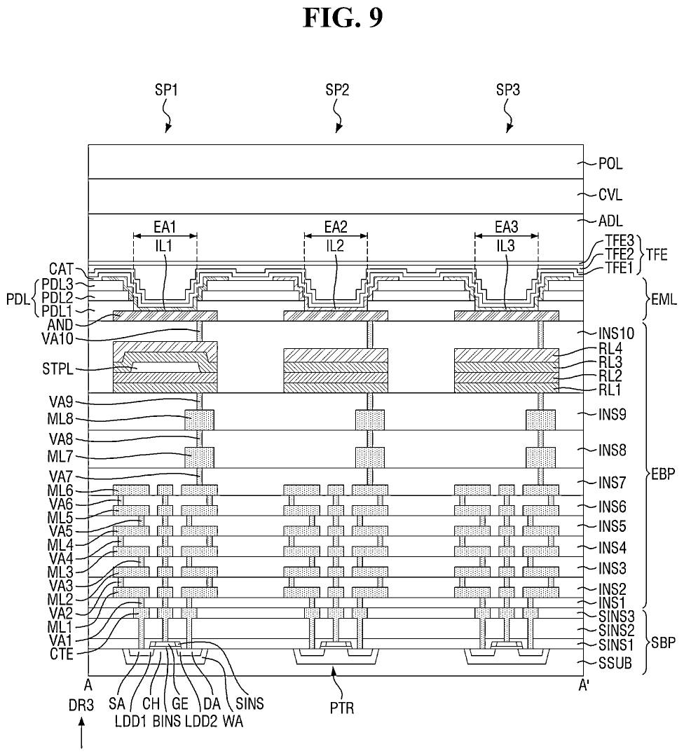

Each of the plurality of pixels includes a plurality of sub-pixels SP1, SP2, and SP3. The plurality of sub-pixels SP1, SP2, and SP3 may include a plurality of pixel transistors as shown in FIG. 7, and the plurality of pixel transistors may be formed by a semiconductor process, and may be located on a semiconductor substrate SSUB (see FIG. 9). For example, the plurality of pixel transistors may be formed of a complementary metal oxide semiconductor (CMOS).

Each of the plurality of sub-pixels SP1, SP2, and SP3 may be connected to any one write scan line GWL among the plurality of write scan lines GWL, any one control scan line GCL among the plurality of control scan lines GCL, any one bias scan line EBL among the plurality of bias scan lines EBL, any one first light emission control line EL1 among the plurality of first light emission control lines EL1, any one second emission control line EL2 among the plurality of second emission control lines EL2, and any one data line DL among the plurality of data lines DL. Each of the plurality of sub-pixels SP1, SP2, and SP3 may receive a data voltage of the data line DL in response to a write scan signal of the write scan line GWL, and may emit light from the light-emitting element according to the data voltage.

The non-display area NDA includes a scan driving area SDA, a data driving area DDA, and a pad area PDA.

The scan driving area SDA may be an area where a scan driver 510 and an emission driver 520 are located. Although it is illustrated in FIG. 5 that the scan driver 510 is located on the left side of the display area DAA, and that the emission driver 520 is located on the right side of the display area DAA, the present disclosure is not limited thereto. For example, the scan driver 510 and the emission driver 520 may be located on both the left side and the right side of the display area DAA.

The scan driver 510 includes a plurality of scan transistors, and the emission driver 520 includes a plurality of light-emitting transistors. The plurality of scan transistors and the plurality of light-emitting transistors may be formed on the semiconductor substrate SSUB (see FIG. 9) through a semiconductor process. For example, the plurality of scan transistors and the plurality of light-emitting transistors may be formed of a CMOS.

The scan driver 510 may include a write scan signal driver 511, a control scan signal driver 512, and a bias scan signal driver 513. Each of the write scan signal driver 511, the control scan signal driver 512, and the bias scan signal driver 513 may receive a scan-timing control signal SCS from the timing control circuit 440. The write scan signal driver 511 may generate write scan signals in response to the scan-timing control signal SCS of the timing control circuit 440, and may sequentially output them to the write scan lines GWL. The control scan signal driver 512 may generate control scan signals in response to the scan-timing control signal SCS, and may sequentially output them to the control scan lines GCL. The bias scan signal driver 513 may generate bias scan signals in response to the scan-timing control signal SCS, and may sequentially output them to the bias scan lines EBL.

The emission driver 520 includes a first emission control driver 521 and a second emission control driver 522. Each of the first emission control driver 521 and the second emission control driver 522 may receive an emission-timing control signal ECS from the timing control circuit 440. The first emission control driver 521 may generate first emission control signals in response to the emission-timing control signal ECS, and may sequentially output them to the first emission control lines EL1. The second emission control driver 522 may generate second emission control signals in response to the emission-timing control signal ECS, and may sequentially output them to the second emission control lines EL2.

The data driving area DDA may be an area where a data driver 530 is located. The data driver 530 may include a plurality of data transistors, and the plurality of data transistors may be formed by a semiconductor process, and may be formed on the semiconductor substrate SSUB (see FIG. 9). For example, the plurality of data transistors may be formed of a CMOS.

The data driver 530 may receive the digital video data DATA and the data-timing control signal DCS from the timing control circuit 440. The data driver 530 converts the digital video data DATA into analog data voltages in response to the data-timing control signal DCS, and outputs them to the data lines DL. In this case, the sub-pixels SP1, SP2, and SP3 are selected by the write scan signal of the scan driver 510, and data voltages may be supplied to the selected sub-pixels SP1, SP2, and SP3.

The pad area PDA includes a plurality of pads PD arranged in the first direction DR1. Each of the plurality of pads PD may be exposed without being covered by a cover layer CVL (see FIG. 9) and a polarizing plate.

The heat dissipation layer 420 may overlap the display panel 410 in the third direction DR3, which is the thickness direction of the display panel 410. The heat dissipation layer 420 may be located on one surface, for example, the rear surface of the display panel 410. The heat dissipation layer 420 serves to dissipate heat generated from the display panel 410. The heat dissipation layer 420 may include a metal layer having high thermal conductivity, such as graphite, silver (Ag), copper (Cu), or aluminum (AI).

The circuit board 430 may be electrically connected to the plurality of pads PD of the pad area PDA of the display panel 410 by using a conductive adhesive member, such as an anisotropic conductive film. The circuit board 430 may be a flexible printed circuit board having a flexible material, or a flexible film. Although it is illustrated in FIG. 4 that the circuit board 430 is unfolded, the circuit board 430 may be bent. In this case, one end of the circuit board 430 may be located on the rear surface of the display panel 410. One end of the circuit board 430 may be opposite to the other end of the circuit board 430 connected to the plurality of pads PD of the pad area PDA of the display panel 410 by using a conductive adhesive member.

The timing control circuit 440 may receive digital video data and timing signals from the outside. The timing control circuit 440 may generate the scan-timing control signal SCS, the emission-timing control signal ECS, and the data-timing control signal DCS for controlling the display panel 410 in response to the timing signals. The timing control circuit 440 may output the scan-timing control signal SCS to the scan driver 510, and may output the emission-timing control signal ECS to the emission driver 520. The timing control circuit 440 may output the digital video data and the data-timing control signal DCS to the data driver 530.

A power supply circuit 450 may generate a plurality of panel-driving voltages in response to the power voltage from the outside. For example, the power supply circuit 450 may generate and supply a first driving voltage VSS, a second driving voltage VDD, and a third driving voltage VINT to the display panel 410. The first driving voltage VSS, the second driving voltage VDD, and the third driving voltage VINT will be described later in conjunction with FIG. 7.

Each of the timing control circuit 440 and the power supply circuit 450 may be formed as an integrated circuit (IC), and may be attached to one surface of the circuit board 430. The scan-timing control signal SCS, the emission-timing control signal ECS, the digital video data DATA, and the data-timing control signal DCS of the timing control circuit 440 may be supplied to the display panel 410 through the circuit board 430. The first driving voltage VSS, the second driving voltage VDD, and the third driving voltage VINT of the power supply circuit 450 may be supplied to the display panel 410 through the circuit board 430.

FIG. 7 is an equivalent circuit diagram of a first sub-pixel according to one or more embodiments.

Referring to FIG. 7, the first sub-pixel SP1 may be connected to the write scan line GWL, the control scan line GCL, the bias scan line EBL, the first emission control line EL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be lower than the third driving voltage VINT. The second driving voltage VDD may be higher than the third driving voltage VINT.

The first sub-pixel SP1 includes a light-emitting element LE and a pixel-driving circuit PC connected to the light-emitting element LE. The pixel-driving circuit PC includes a plurality of transistors T1 to T6, a first capacitor C1, and a second capacitor C2.

The light-emitting element LE emits light in response to a driving current flowing through the channel of the first transistor T1. The emission amount of the light-emitting element LE may be proportional to the driving current. The light-emitting element LE may be located between the fourth transistor T4 and the first driving voltage line VSL. The first electrode of the light-emitting element LE may be connected to the drain electrode of the fourth transistor T4, and the second electrode thereof may be connected to the first driving voltage line VSL. The first electrode of the light-emitting element LE may be an anode electrode (or pixel electrode), and the second electrode of the light-emitting element LE may be a cathode electrode (or common electrode). The light-emitting element LE may be an organic light-emitting diode including a first electrode, a second electrode, and an organic light-emitting layer located between the first electrode and the second electrode, but the present disclosure is not limited thereto. For example, the light-emitting element LE may be an inorganic light-emitting element including a first electrode, a second electrode, and an inorganic semiconductor located between the first electrode and the second electrode, in which case the light-emitting element LE may be a micro light-emitting diode.

The first transistor T1 may be a driving transistor that controls a source-drain current (hereinafter referred to as a “driving current”) flowing between the source electrode and the drain electrode thereof according to a voltage applied to the gate electrode thereof. The first transistor T1 includes a gate electrode connected to the first node N1, a source electrode connected to the drain electrode of the sixth transistor T6, and a drain electrode connected to a second node N2.

The second transistor T2 may be located between one electrode of the first capacitor C1 and the data line DL. The second transistor T2 is turned on by the write scan signal of the write scan line GWL to connect the one electrode of the first capacitor C1 to the data line DL. Accordingly, the data voltage of the data line DL may be applied to the one electrode of the first capacitor C1. The second transistor T2 includes a gate electrode connected to the write scan line GWL, a source electrode connected to the data line DL, and a drain electrode connected to the one electrode of the first capacitor C1.

The third transistor T3 may be located between the first node N1 and the second node N2. The third transistor T3 is turned on by the write control signal of the write control line GCL to connect the first node N1 to the second node N2. For this reason, because the gate electrode and the source electrode of the first transistor T1 are connected, the first transistor T1 may operate like a diode. The third transistor T3 includes a gate electrode connected to the write control line GCL, a source electrode connected to the second node N2, and a drain electrode connected to the first node N1.

The fourth transistor T4 may be connected between the second node N2 and a third node N3. The fourth transistor T4 is turned on by the first emission control signal of the first emission control line EL1 to connect the second node N2 to the third node N3. Accordingly, the driving current of the first transistor T1 may be supplied to the light-emitting element LE. The fourth transistor T4 includes a gate electrode connected to the first emission control line EL1, a source electrode connected to the second node N2, and a drain electrode connected to the third node N3.

The fifth transistor T5 may be located between the third node N3 and the third driving voltage line VIL. The fifth transistor T5 is turned on by the bias scan signal of the bias scan line EBL to connect the third node N3 to the third driving voltage line VIL. Accordingly, the third driving voltage VINT of the third driving voltage line VIL may be applied to the first electrode of the light-emitting element LE. The fifth transistor T5 includes a gate electrode connected to the bias scan line EBL, a source electrode connected to the third node N3, and a drain electrode connected to the third driving voltage line VIL.

The sixth transistor T6 may be located between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and a drain electrode connected to the source electrode of the first transistor T1.

The first capacitor C1 is formed between the first node N1 and the drain electrode of the second transistor T2. The first capacitor C1 includes one electrode connected to the drain electrode of the second transistor T2 and the other electrode connected to the first node N1.

The second capacitor C2 is formed between the gate electrode of the first transistor T1 and the second driving voltage line VDL. The second capacitor C2 includes one electrode connected to the gate electrode of the first transistor T1 and the other electrode connected to the second driving voltage line VDL.

The first node N1 is a junction between the gate electrode of the first transistor T1, the drain electrode of the third transistor T3, the other electrode of the first capacitor C1, and the one electrode of the second capacitor C2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light-emitting element LE.

Each of the first to sixth transistors T1 to T6 may be a metal-oxide-semiconductor field effect transistor (MOSFET). For example, each of the first to sixth transistors T1 to T6 may be a P-type MOSFET, but the present disclosure is not limited thereto. Each of the first to sixth transistors T1 to T6 may be an N-type MOSFET. Alternatively, one or more of the first to sixth transistors T1 to T6 may be P-type MOSFETs, and the remaining transistor(s) may be an N-type MOSFET.

Although it is illustrated in FIG. 7 that the first sub-pixel SP1 includes six transistors T1 to T6 and two capacitors C1 and C2, it should be noted that the equivalent circuit diagram of the first sub-pixel SP1 is not limited to that shown in FIG. 7. For example, the number of transistors and the number of capacitors of the first sub-pixel SP1 are not limited to those shown in FIG. 7.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 7. Therefore, the description of the equivalent circuit diagram of the second sub-pixel SP2 and the equivalent circuit diagram of the third sub-pixel SP3 is omitted in this specification.

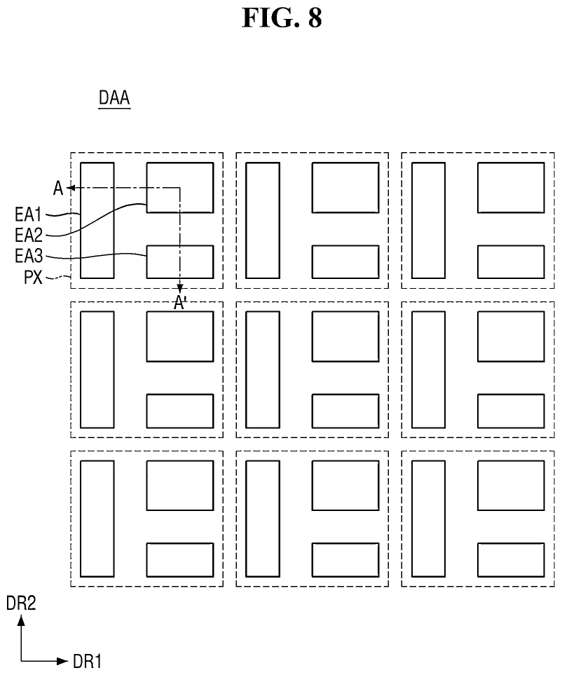

FIG. 8 is a layout view illustrating pixels of a display area according to one or more embodiments.

Referring to FIG. 8, each of the pixels PX includes the first emission area EA1 that is an emission area of the first sub-pixel SP1, the second emission area EA2 that is an emission area of the second sub-pixel SP2, and the third emission area EA3 that is an emission area of the third sub-pixel SP3.

Each of the first emission area EA1, the second emission area EA2, and the third emission area EA3 may have, in plan view, a quadrilateral shape, such as a rectangle, a square, or a diamond. For example, the first emission area EA1 may have a rectangular shape, in plan view, having a short side in the first direction DR1 and a long side in the second direction DR2. In addition, each of the second emission area EA2 and the third emission area EA3 may have a rectangular shape, in plan view, having a long side in the first direction DR1 and a short side in the second direction DR2.

The length of the first emission area EA1 in the first direction DR1 may be less than the length of the second emission area EA2 in the first direction DR1, and may be less than the length of the third emission area EA3 in the first direction DR1.

The length of the second emission area EA2 in the first direction DR1 and the length of the third emission area EA3 in the first direction DR1 may be substantially the same.

The length of the first emission area EA1 in the second direction DR2 may be greater than the sum of the length of the second emission area EA2 in the 1 second direction DR2 and the length of third emission area EA3 in the second direction DR2. The length of the second emission area EA2 in the second direction DR2 may be less than the length of the third emission area EA3 in the second direction DR2.

Although it is illustrated in FIG. 8 that each of the first emission area EA1, the second emission area EA2, and the third emission area EA3 has a rectangular shape, in plan view, the present disclosure is not limited thereto. For example, each of the first emission area EA1, the second emission area EA2, and the third emission area EA3 may have a polygonal shape other than a quadrilateral shape, a circular shape, or an elliptical shape in plan view.

In each of the plurality of pixels PX, the first emission area EA1 and the second emission area EA2 may be adjacent to each other in the first direction DR1.

Further, the first emission area EA1 and the third emission area EA3 may be adjacent to each other in the first direction DR1. In addition, the second emission area EA2 and the third emission area EA3 may be adjacent to each other in the second direction DR2. The area of the first emission area EA1, the area of the second emission area EA2, and the area of the third emission area EA3 may be different.

The first emission area EA1 may emit light of a first color, the second emission area EA2 may emit light of a second color, and the third emission area EA3 may emit light of a third color. Here, the light of the first color may be light of a blue wavelength band, the light of the second color may be light of a green wavelength band, and the light of the third color may be light of a red wavelength band. For example, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red 1 wavelength band may be a wavelength band of light whose main peak wavelength is in the range of about 600 nm to about 750 nm.

It is shown in FIG. 8 that each of the plurality of pixels PX includes three emission areas EA1, EA2, and EA3, but the present disclosure is not limited thereto. That is, each of the plurality of pixels PX may include four emission areas.

In addition, the layout of the emission areas of the plurality of pixels PX is not limited to that illustrated in FIG. 8. For example, the emission areas of the plurality of pixels PX may be arranged in a stripe structure in which the emission areas are arranged in the first direction DR1, a PenTile® structure in which the emission areas are arranged in a diamond shape (e.g., a RGBG matrix structure, a PENTILE™ matrix structure, a PENTILE™ structure, or an RGBG structure, PENTILE™ and PenTile® being registered trademarks of Samsung Display Co., Ltd., Republic of Korea), or a hexagonal structure in which the emission areas having, in plan view, a hexagonal shape are arranged side by side.

FIG. 9 is a cross-sectional view illustrating an example of the display device taken along the line A-A′ of FIG. 8.

Referring to FIG. 9, the display panel 100 includes a semiconductor backplane SBP, a light-emitting element backplane EBP, a light-emitting element layer EML, an encapsulation layer TFE, the cover layer CVL, and a polarizing plate.

The semiconductor backplane SBP includes the semiconductor substrate SSUB including a plurality of pixel transistors PTR, a plurality of semiconductor insulating layers covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 4.

The semiconductor substrate SSUB may be a silicon substrate, a germanium substrate, or a silicon-germanium substrate. The semiconductor substrate SSUB may be a substrate doped with a first type impurity. A plurality of well regions WA may be located on the top surface of the semiconductor substrate SSUB. The plurality of well regions WA may be regions doped with a second type impurity. The second type impurity may be different from the aforementioned first type impurity. For example, when the first type impurity may be a p-type impurity, and the second type impurity may be an n-type impurity. Alternatively, when the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode of the pixel transistor PTR, and a channel region CH located between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. A gate electrode GE of the pixel transistor PTR may overlap the well region WA in the third direction DR3. The channel region CH may overlap the gate electrode GE in the third direction DR3. The source region SA may be located on one side of the gate electrode GE, and the drain region SA may be located on the other side of the gate electrode GE.

Each of the plurality of well regions WA further includes a first low-concentration impurity region LDD1 located between the channel region CH and the source region SA, and a second low-concentration impurity region LDD2 located between the channel region CH and the drain region DA. The first low-concentration impurity region LDD1 may be a region having an impurity concentration that is lower than that of the source region SA. The second low-concentration impurity region LDD2 may be a region having an impurity concentration lower than that of the drain region DA. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that the likelihood of punch-through and hot carrier phenomena that might be caused by a short channel may be reduced or prevented.

A first semiconductor insulating layer SINS1 may be located on the semiconductor substrate SSUB. The first semiconductor insulating layer SINS1 may be formed of silicon carbonitride (SiCN) or a silicon oxide (SiOx)-based inorganic layer, but the present disclosure is not limited thereto.

A second semiconductor insulating layer SINS2 may be located on the first semiconductor insulating layer SINS1. The second semiconductor insulating layer SINS2 may be formed of a silicon oxide (SiOx)-based inorganic layer, but the present disclosure is not limited thereto.

The plurality of contact terminals CTE may be located on the second semiconductor insulating layer SINS2. The contact terminals CTE may be respectively connected to the gate electrode GE, the source region SA, and the drain region DA of the pixel transistors PTR through holes penetrating the first semiconductor insulating layer SINS1 and the second semiconductor insulating layer SINS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating layer SINS3 may be located on a side surface of each of the plurality of contact terminals CTE. The top surface of each of the plurality of contact terminals CTE may be exposed without being covered by the third semiconductor insulating layer SINS3. The third semiconductor insulating 1 layer SINS3 may be formed of a silicon oxide (SiOx)-based inorganic layer, but the present disclosure is not limited thereto.

The semiconductor substrate SSUB may be replaced with a glass substrate or a polymer resin substrate, such as polyimide. In this case, thin film transistors may be located on the glass substrate or the polymer resin substrate. The glass substrate may be a rigid substrate that does not bend, and the polymer resin substrate may be a flexible substrate that may can be bent or curved.

The light-emitting element backplane EBP includes first to eighth metal layers ML1 to ML8, reflective metal layers RL1 to RL4, a plurality of vias VA1 to VA10, and a step layer STPL. In addition, the light-emitting element backplane EBP includes a plurality of interlayer insulating layers INS1 to INS10.

The first to eighth metal layers ML1 to ML8 serve to connect the plurality of contact terminals CTE exposed from the semiconductor backplane SBP to thereby implement the circuit of the first sub-pixel SP1 shown in FIG. 4. That is, the first to sixth transistors T1 to T6 are merely formed on the semiconductor backplane SBP, and the connection of the first to sixth transistors T1 to T6 and the first and second capacitors C1 and C2 is accomplished through the first to eighth metal layers ML1 to ML8. In addition, the connection between the drain region corresponding to the drain electrode of the fourth transistor T4, the source region corresponding to the source electrode of the fifth transistor T5, and the first electrode of the light-emitting element LE is also accomplished through the first to eighth metal layers ML1 to ML8.

The first interlayer insulating layer INS1 may be located on the semiconductor backplane SBP. Each of the first vias VA1 may penetrate the first interlayer insulating layer INS1 to be connected to the contact terminal CTE exposed from the semiconductor backplane SBP. Each of the first metal layers ML1 may be located on the first interlayer insulating layer INS1, and may be connected to the first via VA1.

The second interlayer insulating layer INS2 may be located on the first interlayer insulating layer INS1 and the first metal layers ML1. Each of the second vias VA2 may penetrate the second interlayer insulating layer INS2, and may be connected to the exposed first metal layer ML1. Each of the second metal layers ML2 may be located on the second interlayer insulating layer INS2, and may be connected to the second via VA2.

The third interlayer insulating layer INS3 may be located on the second interlayer insulating layer INS2 and the second metal layers ML2. Each of the third vias VA3 may penetrate the third interlayer insulating layer INS3, and may be connected to the exposed second metal layer ML2. Each of the third metal layers ML3 may be located on the third interlayer insulating layer INS3, and may be connected to the third via VA3.

A fourth interlayer insulating layer INS4 may be located on the third interlayer insulating layer INS3 and the third metal layers ML3. Each of the fourth vias VA4 may penetrate the fourth interlayer insulating layer INS4, and may be connected to the exposed third metal layer ML3. Each of the fourth metal layers ML4 may be located on the fourth interlayer insulating layer INS4, and may be connected to the fourth via VA4.

A fifth interlayer insulating layer INS5 may be located on the fourth interlayer insulating layer INS4 and the fourth metal layers ML4. Each of the fifth vias VA5 may penetrate the fifth interlayer insulating layer INS5, and may be connected to the exposed fourth metal layer ML4. Each of the fifth metal layers ML5 may be located on the fifth interlayer insulating layer INS5, and may be connected to the fifth via VA5.

A sixth interlayer insulating layer INS6 may be located on the fifth interlayer insulating layer INS5 and the fifth metal layers ML5. Each of the sixth vias VA6 may penetrate the sixth interlayer insulating layer INS6, and may be connected to the exposed fifth metal layer ML5. Each of the sixth metal layers ML6 may be 1 located on the sixth interlayer insulating layer INS6, and may be connected to the sixth via VA6.

A seventh interlayer insulating layer INS7 may be located on the sixth interlayer insulating layer INS6 and the sixth metal layers ML6. Each of the seventh vias VA7 may penetrate the seventh interlayer insulating layer INS7, and may be connected to the exposed sixth metal layer ML6. Each of the seventh metal layers ML7 may be located on the seventh interlayer insulating layer INS7, and may be connected to the seventh via VA7.

An eighth interlayer insulating layer INS8 may be located on the seventh interlayer insulating layer INS7 and the seventh metal layers ML7. Each of the eighth vias VA8 may penetrate the eighth interlayer insulating layer INS8, and may be connected to the exposed seventh metal layer ML7. Each of the eighth metal layers ML8 may be located on the eighth interlayer insulating layer INS8, and may be connected to the eighth via VA8.

The first to eighth metal layers ML1 to ML8 and the first to eighth vias VA1 to VA8 may be formed of substantially the same material. The first to eighth metal layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. The first to eighth vias VA1 to VA8 may be made of substantially the same material. First to eighth interlayer insulating layers INS1 to INS8 may be formed of a silicon oxide (SiOx)-based inorganic layer, but the present disclosure is not limited thereto.

The thicknesses of the first metal layer ML1, the second metal layer ML2, the third metal layer ML3, the fourth metal layer ML4, the fifth metal layer ML5, and the sixth metal layer ML6 may be greater than the thicknesses of the first via VA1, the second via VA2, the third via VA3, the fourth via VA4, the fifth via VA5, and the sixth via VA6, respectively. The thickness of each of the second metal layer ML2, the third metal layer ML3, the fourth metal layer ML4, the fifth metal layer ML5, and the sixth metal layer ML6 may be greater than the thickness of the first metal layer ML1. The thickness of the second metal layer ML2, the thickness of the third metal layer ML3, the thickness of the fourth metal layer ML4, the thickness of the fifth metal layer ML5, and the thickness of the sixth metal layer ML6 may be substantially the same. For example, the thickness of the first metal layer ML1 may be about 1360 Å, the thickness of each of the second metal layer ML2, the third metal layer ML3, the fourth metal layer ML4, the fifth metal layer ML5, and the sixth metal layer ML6 may be about 1440 Å, and the thickness of each of the first via VA1, the second via VA2, the third via VA3, the fourth via VA4, the fifth via VA5, and the sixth via VA6 may be about 1150 Å.

The thickness of each of the seventh metal layer ML7 and the eighth metal layer ML8 may be greater than each of the thickness of the first metal layer ML1, the thickness of the second metal layer ML2, the thickness of the third metal layer ML3, the thickness of the fourth metal layer ML4, the thickness of the fifth metal layer ML5, and the sixth metal layer ML6. The thickness of each of the seventh metal layer ML7 and the thickness of the eighth metal layer ML8 may be greater than the thickness of the seventh via VA7 and the thickness of the eighth via VA8.

The thickness of each of the seventh via VA7 and the eighth via VA8 may be greater than each of the thickness of the first via VA1, the thickness of the second via VA2, the thickness of the third via VA3, the thickness of the fourth via VA4, the thickness of the fifth via VA5, and the thickness of the sixth via VA6. The thickness of the seventh metal layer ML7 and the thickness of the eighth metal layer ML8 may be substantially the same. For example, the thickness of each of the seventh metal layer ML7 and the eighth metal layer ML8 may be about 9000 Å. The thickness of each of the seventh via VA7 and the eighth via VA8 may be about 6000 Å.

A ninth interlayer insulating layer INS9 may be located on the eighth interlayer insulating layer INS8 and the eighth metal layers ML8. The ninth insulating layer INS9 may be formed of a silicon oxide (SiOx)-based inorganic layer, but the present disclosure is not limited thereto.

Each of the ninth vias VA9 may penetrate the ninth interlayer insulating layer INS9, and may be connected to the exposed eighth metal layer ML8. The ninth vias VA9 may be formed of any one of copper (Cu), aluminum (AI), tungsten (W), molybdenum (Mo), chromium (Cr), gold (Au), titanium (Ti), nickel (Ni), or neodymium (Nd), or an alloy including any one of them. The thickness of the ninth via VA9 may be about 16500 Å.

Each of the first reflective electrodes RL1 may be located on the ninth interlayer insulating layer INS9, and may be connected to the ninth via VA9. The first reflective electrodes RL1 may be formed of any one of copper (Cu), aluminum (AI), tungsten (W), molybdenum (Mo), chromium (Cr), gold (Au), titanium (Ti), nickel (Ni), or neodymium (Nd), or an alloy including any one of them.

Each of the second reflective electrodes RL2 may be located on the first reflective electrode RL1. The second reflective electrodes RL2 may be formed of any one of copper (Cu), aluminum (AI), tungsten (W), molybdenum (Mo), chromium (Cr), gold (Au), titanium (Ti), nickel (Ni), or neodymium (Nd), or an alloy including any one of them. For example, the second reflective electrodes RL2 may be made of titanium nitride (TiN).

In the first sub-pixel SP1, the step layer STPL may be located on the second reflective electrode RL2. The step layer STPL may not be located in each of the second sub-pixel SP2 and the third sub-pixel SP3. To suitably reflect the light of the first color emitted from a first light-emitting layer EML1 of the first sub-pixel SP1, the thickness of the step layer STPL may be set in consideration of the wavelength of the light of the first color and the distance from the first light-emitting layer EML1 to the fourth reflective electrode RL4. The step layer STPL may be formed of silicon carbonitride (SiCN) or a silicon oxide (SiOx)-based inorganic layer, but the present disclosure is not limited thereto. The thickness of the step layer STPL may be about 400 Å.

In the first sub-pixel SP1, the third reflective electrode RL3 may be located on the second reflective electrode RL2 and the step layer STPL. In the second sub-pixel SP2 and the third sub-pixel SP3, the third reflective electrode RL3 may be located on the second reflective electrode RL2. The third reflective electrodes RL3 may be formed of any one of copper (Cu), aluminum (AI), tungsten (W), molybdenum (Mo), chromium (Cr), gold (Au), titanium (Ti), nickel (Ni), or neodymium (Nd), or an alloy including any one of them.

In one or more embodiments, at least one of the first reflective electrode RL1, the second reflective electrode RL2, or the third reflective electrode RL3 may be omitted.

The fourth reflective electrodes RL4 may be respectively located on the third reflective electrodes RL3. The fourth reflective electrodes RL4 may reflect light from first to third light-emitting layers EML1, EML2, and EML3. The fourth reflective electrodes RL4 may include a metal having high reflectivity to suitably reflect the light. The fourth reflective electrodes RL4 may be formed of aluminum (AI), a stacked structure (Ti/Al/Ti) of aluminum and titanium, a stacked structure (ITO/Al/ITO) of aluminum and ITO, an APC alloy, which is an alloy of silver (Ag), palladium (Pd), and copper (Cu), and a stacked structure (ITO/APC/ITO) of the APC alloy and ITO, but the present disclosure is not limited thereto. Each of the fourth reflective electrodes RL4 may have a thickness of about 850 Å.

A tenth interlayer insulating layer INS10 may be located on the ninth interlayer insulating layer INS9 and the fourth reflective electrodes RL4. The tenth insulating layer INS10 may be formed of a silicon oxide (SiOx)-based inorganic layer, but the present disclosure is not limited thereto.

Each of the tenth vias VA10 may penetrate the tenth interlayer insulating layer INS10, and may be connected to the fourth reflective electrodes RL4. The tenth vias VA10 may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. Due to the presence of the step layer STPL, the thickness of the tenth via VA10 (e.g., in the thickness direction DR3) in the first sub-pixel SP1 may be less than the thickness of the tenth via VA10 in each of the second sub-pixel SP2 and the third sub-pixel SP3. For example, the thickness of the tenth via VA10 in the first sub-pixel SP1 may be about 800 Å, and the thickness of the tenth via VA10 in each of the second sub-pixel SP2 and the third sub-pixel SP3 may be about 1200 Å.

The light-emitting element layer EML may be located on the light-emitting element backplane EBP. The light-emitting element layer EML may include the light-emitting elements LE each having a first electrode AND, first to third light-emitting layers IL1, IL2, IL3, and a second electrode CAT, and a pixel-defining layer PDL.

The first electrode AND of each of the light-emitting elements LE may be located on the tenth interlayer insulating layer INS10, and may be connected to the tenth via VA10. The first electrode AND of each of the light-emitting elements LE may be connected to the drain region DA or source region SA of the pixel transistor PTR through the tenth via VA10, the first to fourth reflective electrodes RL1 to RL4, the first to ninth vias VA1 to VA9, the first to eighth metal layers ML1 to ML8, and the contact terminal CTE. The first electrode AND of each of the light-emitting elements LE may be formed of any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the first electrode AND of each of the light-emitting elements LE may be titanium nitride (TiN).

The pixel-defining layer PDL may be located on a part of the first electrode AND of each of the light-emitting elements LE. The pixel-defining layer PDL may cover the edge of the first electrode AND of each of the light-emitting elements LE. The pixel-defining layer PDL may serve to partition the first emission areas EA1, the second emission areas EA2, and the third emission areas EA3.

The first emission area EA1 may be defined as an area in which the first electrode AND, the first light-emitting layer IL1, and the second electrode CAT are sequentially stacked in the first sub-pixel SP1 to emit light. The second emission area EA2 may be defined as an area in which the first electrode AND, the second light-emitting layer IL2, and the second electrode CAT are sequentially stacked in the second sub-pixel SP2 to emit light. The third emission area EA3 may be defined as an area in which the first electrode AND, the third light-emitting layer IL3, and the second electrode CAT are sequentially stacked in the third sub-pixel SP3 to emit light.

The pixel-defining layer PDL may include first to third pixel-defining layers PDL1, PDL2, and PDL3. The first pixel-defining layer PDL1 may be located on the edge of the first electrode AND of each of the light-emitting elements LE, the second pixel-defining layer PDL2 may be located on the first pixel-defining layer PDL1, and the third pixel-defining layer PDL3 may be located on the second pixel-defining layer PDL2. The first pixel-defining layer PDL1, the second pixel-defining layer PDL2, and the third pixel-defining layer PDL3 may be formed of a silicon oxide (SiOₓ)-based inorganic layer, but the present disclosure is not limited thereto. The first pixel-defining layer PDL1, the second pixel-defining layer PDL2, and the third pixel-defining layer PDL3 may each have a thickness of about 500 Å.

the first emission area EA1 includes a first light-emitting layer IL1 that emits the first light, the second emission area EA2 includes a second light-emitting layer IL2 that emits the second light, and the third emission area EA3 includes a third light-emitting layer IL3 that emits the third light. the first light-emitting layer IL1 may be disposed on the first electrode AND that is exposed without being covered by the first pixel defining film PDL1 in the first emission area EA1. The first light-emitting layer IL1 may be disposed on the first pixel defining film PDL1, the second pixel defining film PDL2, and the third pixel defining film PDL3.

The second light-emitting layer IL2 may be disposed on the first electrode AND that is exposed without being covered by the first pixel defining film PDL1 in the second emission area EA2. The second light-emitting layer IL2 may be disposed on the first pixel defining film PDL1, the second pixel defining film PDL2, and the third pixel defining film PDL3.

The third light-emitting layer IL3 may be disposed on the first electrode AND that is exposed without being covered by the first pixel defining film PDL1 in the third emission area EA3. The third light-emitting layer IL3 may be disposed on the first pixel defining film PDL1, the second pixel defining film PDL2, and the third pixel defining film PDL3.

The first light-emitting layer IL1, the second light-emitting layer IL2, and the third light-emitting layer IL3 may be disposed to be spaced apart from each other.

The second electrode CAT may be located on the first light-emitting layer IL1, the second light-emitting layer IL2, and the third light-emitting layer IL3. The second electrode CAT may be formed of a transparent conductive material (TCO), such as ITO or IZO, that can transmit light, or may be formed of a semi-transmissive conductive material, such as magnesium (Mg), silver (Ag), or an alloy of Mg and Ag. When the second electrode CAT is formed of a semi-transmissive conductive material, the light emission efficiency may be improved in each of the first to third sub-pixels SP1, SP2, and SP3 due to a micro-cavity effect.

The encapsulation layer TFE may be located on the light-emitting element layer EML. The encapsulation layer TFE may include at least one inorganic layer TFE1 and TFE2 to reduce or prevent oxygen or moisture from permeating into the light-emitting element layer EML. In addition, the encapsulation layer ENC may include at least one organic layer to protect the light-emitting element layer EML from foreign substances, such as dust. For example, the encapsulation layer ENC may include a first encapsulation inorganic layer TFE1, an encapsulation organic layer TFE2, and a second encapsulation inorganic layer TFE3.

The first encapsulation inorganic layer TFE1 may be located on the second electrode CAT, the encapsulation organic layer TFE2 may be located on the first encapsulation inorganic layer TFE1, and the second encapsulation inorganic layer TFE3 may be located on the encapsulation organic layer TFE2. The first encapsulation inorganic layer TFE1 and the second encapsulation inorganic layer TFE3 may be formed of multiple layers in which one or more inorganic layers of silicon nitride (SiNₓ), silicon oxynitride (SiON), silicon oxide (SiOₓ), titanium oxide (TiOₓ), and aluminum oxide (AlOₓ) layers are alternately stacked. The encapsulation organic layer TFE2 may be a monomer. Alternatively, the encapsulation organic layer TFE2 may be an organic layer, such as acryl resin, epoxy resin, phenolic resin, polyamide resin, polyimide resin or the like.

An adhesive layer ADL may be a layer for bonding the encapsulation layer TFE to the cover layer CVL. The adhesive layer ADL may be a double-sided adhesive member. In addition, the adhesive layer ADL may be a transparent adhesive member, such as a transparent adhesive or a transparent adhesive resin.

The cover layer CVL may be a glass substrate or a polymer resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

In one or more embodiments, a polarizing plate may be located on one surface of the cover layer CVL. The polarizing plate may be a structure for reducing or preventing visibility degradation caused by reflection of external light. The polarizing plate may include a linear polarizing plate and a phase retardation film. For example, the phase retardation film may be a λ/4 plate (quarter-wave plate), but the present disclosure is not limited thereto.

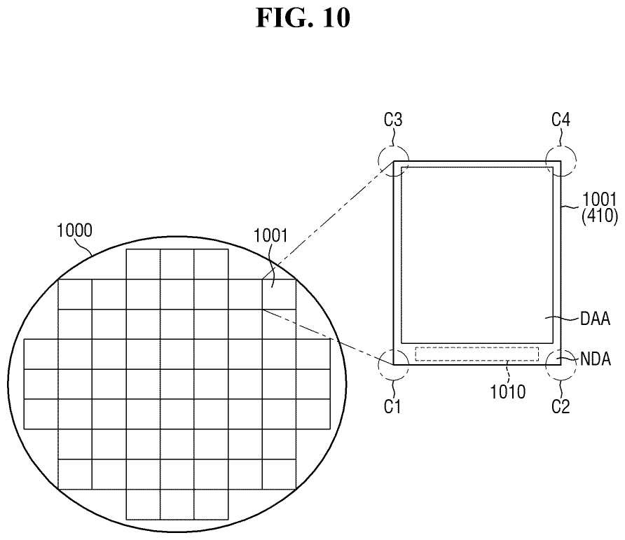

FIG. 10 is a diagram illustrating an example of a mother substrate for manufacturing a display panel according to one or more embodiments.

Referring to FIG. 10, a mother substrate 1000 may be a semiconductor wafer for OLEDoS. In this disclosure, a semiconductor wafer may be referred to as “semiconductor substrate,” “substrate,” or “semiconductor wafer substrate.”

The mother substrate 1000 may include a plurality of net dies 1001. One net die 1001 may correspond to one display panel 410. For example, the mother substrate 1000, which is a semiconductor wafer, may include about 76 net dies 1001. This means that about 76 display panels 410 may be manufactured from one mother substrate 1000.

The plurality of display panels 410 manufactured on the mother substrate 1000 may be individually separated by a sawing process and a grinding process in which the corners of each display panel 410 are polished into a round shape after the sawing process.

The display panel 410 may include the display area DAA where a light-emitting element is located, and the non-display area NDA located outside the display area DAA.

A driving circuit 1010 may be located in the non-display area NDA of the display panel 410. The driving circuit 1010 may include the data driver 530 described in conjunction with FIG. 5. For example, the driving circuit 1010 may be located at one end of the display panel 410. Accordingly, the display panel 410 may be defined as including a first corner C1 and a second corner C2 that are adjacent to the driving circuit, and a third corner C3 and a fourth corner C4 that are not adjacent to the driving circuit. In the illustrated example, the driving circuit 1010 is located at the bottom of the display panel 410. Accordingly, in the illustrated example, the first corner C1 and the second corner C2 may be located at the bottom of the display panel 410, and the third corner C3 and the fourth corner C4 may be located at the top of the display panel 410.

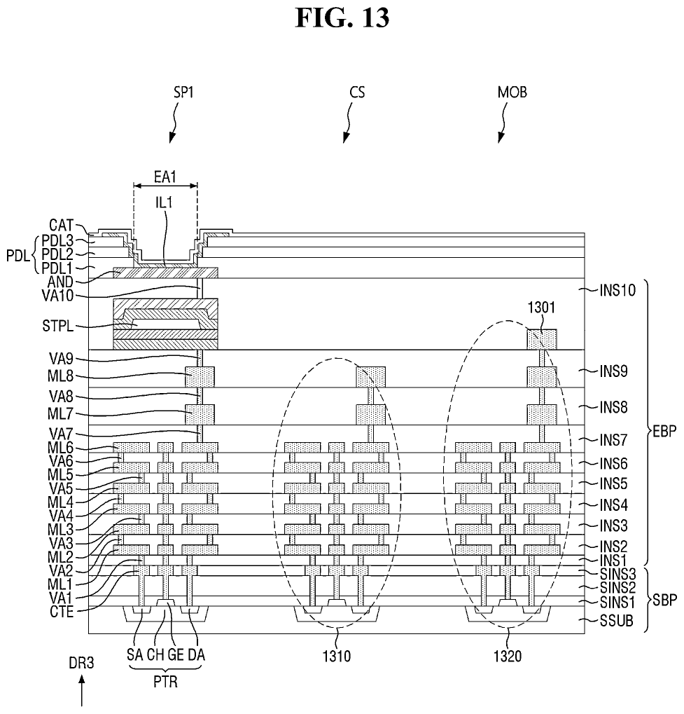

In general, the third corner C3 and the fourth corner C4, in which the driving circuit 1010 is not located, are relatively closer to the display area DAA compared to the first corner C1 and the second corner C2. Accordingly, a part of the display area DAA adjacent to the third corner C3 and/or the fourth corner C4 is more likely to be damaged during the sawing process and the grinding process. In one or more embodiments of the present disclosure, a permeation prevention region MOB (see FIG. 13) is located at the outermost periphery of the non-display area NDA, and a crack prevention region CS (see FIG. 13) is located outside the permeation prevention region MOB, thereby reducing or preventing the likelihood of damage to the display panel 410 or of permeation of moisture and oxygen that may occur during the sawing process and the grinding process. For example, in one or more embodiments of the present disclosure, because the crack prevention region CS is located in a double line shape at the third corner C3 and the fourth corner C4, which are located relatively closer to the display area DAA, it is possible to reduce or prevent damage to the display panel 410, and to increase reliability.

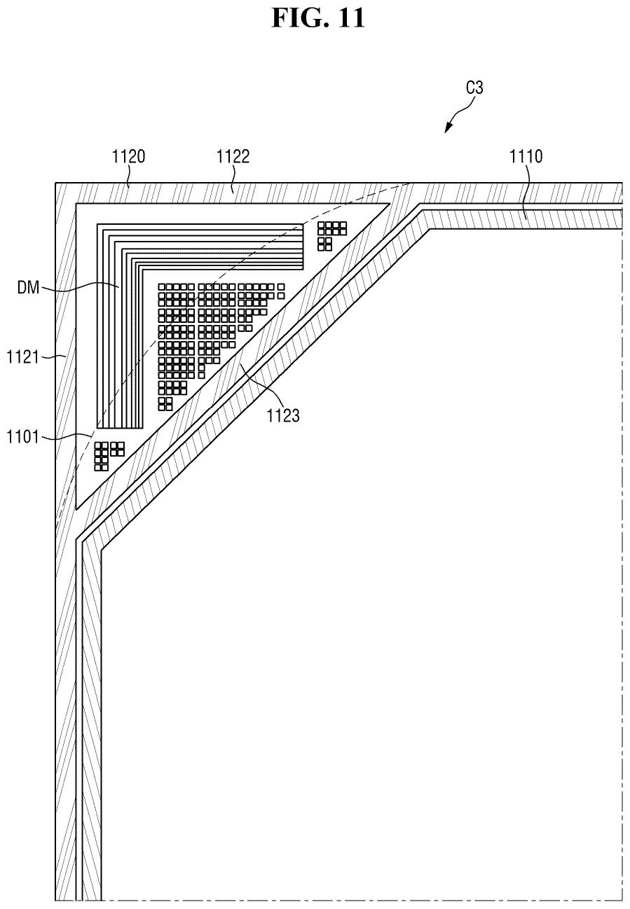

Hereinafter, detailed description will be made on the display device 10 according to one or more embodiments, in which the crack prevention region CS is located in a double line shape at the third corner C3 and the fourth corner C4, in conjunction with FIGS. 11 to 13.

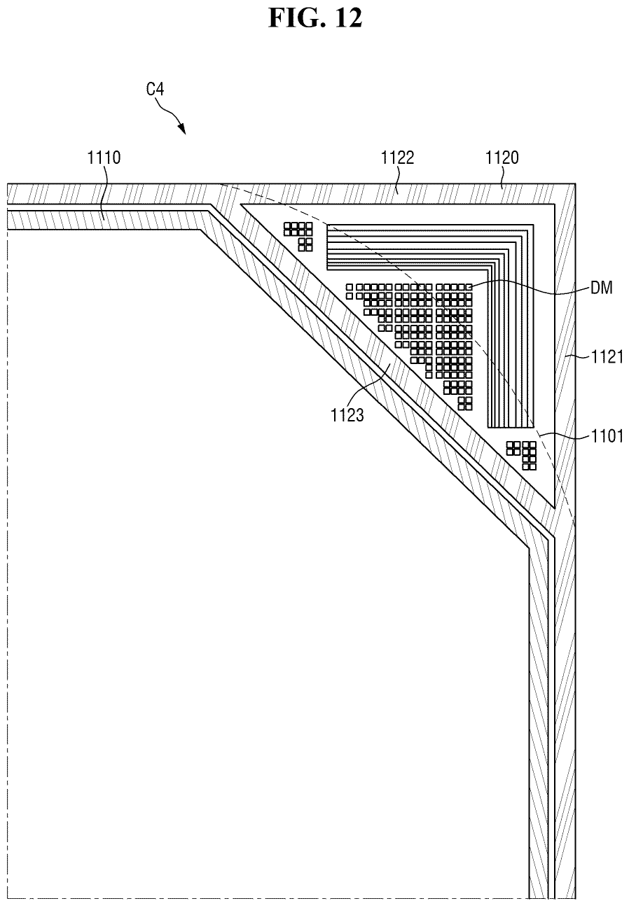

FIG. 11 is an enlarged plan view of the third corner C3 of the display panel 410 according to one or more embodiments. FIG. 12 is an enlarged plan view of the fourth corner C4 of the display panel 410 according to one or more embodiments.

Hereinafter, description in conjunction with FIGS. 11 and 12 relates to the shape and position of the crack prevention region CS and the permeation prevention region MOB when viewed from the front of the display panel 410. In this 1 case, viewing the display panel 410 from the front may mean viewing the display panel 410 in a direction normal to the plane that defines the front of the display panel 410.

In FIGS. 11 and 12, reference numeral 1110 represents an imaginary line where the permeation prevention region MOB is located.

In FIGS. 11 and 12, reference numeral 1120 represents an imaginary line where the crack prevention region CS is located.

Referring to FIGS. 11 and 12, the permeation prevention region MOB, and the crack prevention region CS located outside the permeation prevention region MOB, may be located at the outermost periphery of the display panel 410. The crack prevention region CS may be substantially a region located at the outermost periphery of the display panel 410.

According to one or more embodiments, the permeation prevention region MOB and the crack prevention region CS may be located to surround the periphery of the display panel 410. At the third corner C3 and the fourth corner C4, the crack prevention region CS may be located in a double line shape. In this case, the fact that the crack prevention region CS is located in a double line shape may mean that the crack prevention regions CS are located to be spaced apart at a corresponding interval at the third corner C3 and the fourth corner C4 when viewed from the front of the display panel 410.

In one or more embodiments, at the first corner C1 and the second corner C2, the crack prevention region CS may be located in a single line shape, and the permeation prevention region MOB may be located in a single line shape inside the crack prevention region CS.

According to one or more embodiments, at the third corner C3 and the fourth corner C4, the permeation prevention region MOB is located inside the crack prevention region CS while surrounding the periphery of the display panel 410 in a single line shape.

According to one or more embodiments, the crack prevention region CS may be located in a right triangular shape at the third corner C3 and the fourth corner C4. For example, at the third corner C3 and the fourth corner C4, the crack prevention region CS may include a first portion 1121 that forms a part of a first side surface of the display panel 410, a second portion 1122 that extends from the first portion 1121 in the vertical direction to form a part of a second side surface of the display panel 410, and a third portion 1123 that is located to connect the first portion 1121 to the second portion 1122 in the diagonal direction. At the third corner C3 and the fourth corner C4, the third portion 1123 of the crack prevention region CS may substantially form a hypotenuse of the crack prevention region CS located in the right triangular shape.

According to one or more embodiments, at the third corner C3 and the fourth corner C4, the permeation prevention region MOB may be located inside the third portion 1123 of the crack prevention region CS (e.g., between the first, second, and third portions 1121, 1122, and 1123) to be in parallel with the third portion 1123.

According to one or more embodiments, as the crack prevention region CS is located in the right triangular shape at the third corner C3 and the fourth corner C4, it is possible to reduce or prevent the likelihood of a defect in which the permeation prevention region MOB is removed during the grinding process of polishing the corners of the display panel 410.

In FIGS. 11 and 12, dotted line 1101 represents a polishing line 1101 for the grinding process. That is, each corner of the display panel 410 may be polished into a round shape along the polishing line 1101, and the outermost periphery of the display panel 410 located on the outside of the polishing line 1101 may be removed in the polishing process. As illustrated, the crack prevention region CS is located in a double line shape (e.g., right triangular shape) at the third corner C3 and the fourth corner C4, so that a part of the crack prevention region CS located on the outside of the polishing line may be removed, but the permeation prevention region MOB may not be removed. That is, because the permeation prevention region MOB is located not only on the inside of the polishing line, but also inside the third portion of the crack prevention region CS, the permeation prevention region MOB may not be removed or damaged at the third corner C3 and the fourth corner C4 even after the grinding process. In one or more embodiments of the present disclosure, it is possible to protect the display panel 410 from cracks that may occur during the sawing process and the grinding process, and to reduce or prevent moisture and oxygen from permeating into the display panel 410.

Meanwhile, as shown, a dummy structure DM may be located inside the crack prevention region CS located in the right triangular shape at the third corner C3 and the fourth corner C4. In one or more embodiments, the dummy structure DM may include dummy metal layers located in the same layer as the plurality of metal layers ML1 to ML8 (see FIG. 9) of the display panel 410.

FIG. 13 is a partial cross-sectional view of the display panel 410, illustrating a stacked structure of the crack prevention region CS and the permeation prevention region MOB according to one or more embodiments.

The crack prevention region CS and the permeation prevention region MOB shown in FIG. 13 may be a part of the crack prevention region CS and the permeation prevention region MOB shown in FIGS. 11 and 12. The first sub-pixel SP1 shown in FIG. 13 may be substantially the same as the first sub-pixel SP1 shown in FIG. 9.

Referring to FIG. 13, the display panel 410 may include the semiconductor substrate SSUB, the semiconductor backplane SBP located on the semiconductor substrate SSUB, the light-emitting element backplane EBP having the plurality of metal layers ML1 to ML8 (see FIG. 9), and the light-emitting element layer EML located on the light-emitting element backplane EBP.

According to one or more embodiments, the stacked structure of the permeation prevention region MOB may include a plurality of permeation prevention metal layers 1320 located in the same layer as the plurality of metal layers ML1 to ML8 (see FIG. 9) of the light-emitting element backplane EBP. For example, the plurality of permeation prevention metal layers 1320 may be located in the same layer as the plurality of metal layers ML1 to ML8 (see FIG. 9) of the light-emitting element backplane EBP located in the display area DAA, in the permeation prevention region MOB. The plurality of permeation prevention metal layers 1320 may be located to surround the periphery of the display panel 410.

According to one or more embodiments, the stacked structure of the crack prevention region CS may include a plurality of crack prevention metal layers 1310 located in the same layer as the plurality of metal layers ML1 to ML8 (see FIG. 9) of the light-emitting element backplane EBP. For example, the plurality of crack prevention metal layers 1310 may be located at the same layer as the plurality of metal layers ML1 to ML8 (see FIG. 9) of the light-emitting element backplane EBP located in the display area DAA, and in the crack prevention region CS. The plurality of crack prevention metal layers 1310 may be located to surround the outermost periphery of the display panel 410. For example, as the plurality of crack prevention metal layers 1310 are located in a double line shape at the third corner C3 and the fourth corner C4 of the display panel 410, it is possible to reduce or prevent the likelihood of the permeation prevention region MOB being removed during the grinding process.

Reference numeral 1301 of FIG. 13 may correspond to a pad metal layer 1301 located on the plurality of permeation prevention metal layers in the permeation prevention region MOB. In one or more embodiments, the pad metal layer 1301 may be a metal layer located in the same layer as pad electrodes of the display panel 410.

According to the display device and the mobile electronic device including the same according to the embodiments, the display panel may be protected from cracks that may occur during the sawing process and the grinding process, and the likelihood of moisture and oxygen permeating into the display panel may be reduced or prevented.

In concluding the detailed description, those skilled in the art will appreciate that many variations and modifications can be made to the preferred embodiments without substantially departing from the aspects of the present disclosure.

Therefore, the disclosed embodiments are used in a generic and descriptive sense only and not for purposes of limitation.

What is claimed is:

1. A display device comprising a display panel having a display area in which a light-emitting element is located, and a non-display area outside the display area in plan view and comprising a permeation prevention region outside an encapsulation area, and a crack prevention region outside the permeation prevention region and in a double line shape at at least one corner of the display panel.

2. The display device of claim 1, further comprising a driving circuit at one end of the display panel,
wherein the display panel is defined comprises a first corner and a second corner adjacent to the driving circuit, and a third corner and a fourth corner not adjacent to the driving circuit, and
wherein the crack prevention region is in the double line shape at the third corner and the fourth corner of the display panel.

3. The display device of claim 2, wherein the crack prevention region is in a single line shape at the first corner and the second corner of the display panel.

4. The display device of claim 2, wherein the crack prevention region is in a right triangular shape at the third corner or the fourth corner of the display panel.

5. The display device of claim 4, wherein, at the third corner or the fourth corner of the display panel, the crack prevention region comprises a first portion forming a part of a first side surface of the display panel, a second portion extending from the first portion in a vertical direction to form a part of a second side surface of the display panel, and a third portion to connect the first portion to the second portion in a diagonal direction.

6. The display device of claim 1, wherein, at the third corner or the fourth corner of the display panel, the permeation prevention region is inside the third portion of the crack prevention region to be in parallel with the third portion.

7. The display device of claim 4, wherein, at the third corner or the fourth corner of the display panel, a dummy structure is in the crack prevention region in the right triangular shape.

8. The display device of claim 7, wherein the display panel comprises a semiconductor substrate, a semiconductor backplane above the semiconductor substrate, a light-emitting element backplane having metal layers, and a light-emitting element layer above the light-emitting element backplane.

9. The display device of claim 8, wherein a stacked structure of the permeation prevention region comprises permeation prevention metal layers at a same layer as the metal layers of the light-emitting element backplane.

10. The display device of claim 8, wherein a stacked structure of the crack prevention region comprises permeation prevention metal layers at a same layer as the metal layers of the light-emitting element backplane.

11. A mobile electronic device comprising a display panel comprising a display area in which a light-emitting element is located, and a non-display area outside the display area and comprising a permeation prevention region outside an encapsulation area, and a crack prevention region outside the permeation prevention region in a double line shape at at least one corner of the display panel.

12. The mobile electronic device of claim 11, further comprising a driving circuit at one end of the display panel,
wherein the display panel comprises a first corner and a second corner adjacent to the driving circuit, and a third corner and a fourth corner not adjacent to the driving circuit, and
wherein the crack prevention region is in the double line shape at the third corner and the fourth corner of the display panel.

13. The mobile electronic device of claim 12, wherein the crack prevention region is in a single line shape at the first corner and the second corner of the display panel.

14. The mobile electronic device of claim 12, wherein the crack prevention region is in a right triangular shape at the third corner or the fourth corner of the display panel.

15. The mobile electronic device of claim 14, wherein, at the third corner or the fourth corner of the display panel, the crack prevention region comprises a first portion forming a part of a first side surface of the display panel, a second portion extending from the first portion in a vertical direction to form a part of a second side surface of the display panel, and a third portion to connect the first portion to the second portion in a diagonal direction.

16. The mobile electronic device of claim 15, wherein, at the third corner or the fourth corner of the display panel, the permeation prevention region is inside the third portion of the crack prevention region to be in parallel with the third portion.

17. The mobile electronic device of claim 14, wherein, at the third corner or the fourth corner of the display panel, a dummy structure is inside the crack prevention region in the right triangular shape.

18. The mobile electronic device of claim 17, wherein the display panel comprises a semiconductor substrate, a semiconductor backplane above the semiconductor substrate, a light-emitting element backplane having metal layers, and a light-emitting element layer above the light-emitting element backplane.

19. The mobile electronic device of claim 18, wherein a stacked structure of the permeation prevention region comprises permeation prevention metal layers at a same layer as the metal layers of the light-emitting element backplane.

20. The mobile electronic device of claim 18, wherein a stacked structure of the crack prevention region comprises permeation prevention metal layers at a same layer as the metal layers of the light-emitting element backplane.
